(19) United States
(12) Patent Application Publication
(10) Pub. No.: US 2026/0361297 A1
(43) Pub. Date: Nov. 12, 2026

(54) PROTECTION SWITCH WITH CURRENT LIMIT CIRCUITRY

(71) Applicant: TEXAS INSTRUMENTS INCORPORATED, Dallas, TX (US)

(72) Inventor: Ramesh Chandrasekaran, Plano, TX (US)

(21) Appl. No.: 19/287,525

(22) Filed: Jul. 31, 2025

Related U.S. Application Data
(60) Provisional application No. 63/802,862, filed on May 9, 2025.

(51) Int. Cl. H03K 17/08

(52) U.S. Cl. CPC H03K 17/08

(57) ABSTRACT

An electronic circuit comprises a first transistor having a control terminal, a first current path terminal, and a second current path terminal, and a second transistor having a control terminal, a first current path terminal, and a second current path terminal, wherein the first current path terminal of the first transistor is coupled to the first current path terminal of the second transistor. The electronic circuit further comprises a control circuit to receive a first bias control signal and a second bias control signal, provide a first control signal to the control terminal of the first transistor to transition the first transistor between a linear and a saturation region based on the first bias control signal, and provide a second control signal to the control terminal of the second transistor to transition the second transistor between a linear and a saturation region based on the second bias control signal.

### RELATED APPLICATION

This application claims priority to U.S. Provisional Application No. 63/802,862, filed May 9, 2025, entitled “CURRENT LIMIT CIRCUITRY FOR A HIGH PRECISION CMOS PROTECTION SWITCH WITH A BIASED SUBSTRATE AND FLOATING SWITCH GATE DRIVE,” which application is hereby incorporated by reference.

### TECHNICAL FIELD

The present disclosure relates generally to an electronic system and method, and, in particular embodiments, to a protection switch with current limit circuitry.

### BACKGROUND

Sense and control modules, e.g., in factory automation applications may be made for specific purposes, for example, current sense, temperature sense, etc.

### SUMMARY

In accordance to an embodiment, an electronic circuit includes: a first transistor having a control terminal, a first current path terminal, and a second current path terminal; a second transistor having a control terminal, a first current path terminal, and a second current path terminal, where the first current path terminal of the first transistor is coupled to the first current path terminal of the second transistor; and a control circuit configurable to: receive a first bias control signal; receive a second bias control signal; provide a first control signal to the control terminal of the first transistor to transition the first transistor between a linear region and a saturation region based on the first bias control signal; and provide a second control signal to the control terminal of the second transistor to transition the second transistor between a linear region and a saturation region based on the second bias control signal.

In accordance to an embodiment, an electronic circuit includes: a first transistor having a first terminal, a second terminal, and a control terminal coupled to a first signal terminal; a second transistor having a first terminal, a second terminal, and a control terminal coupled to a second signal terminal; a third transistor having a first terminal, a second terminal, and a control terminal coupled to a third signal terminal, and where the second terminals of the first, second and third transistors are coupled to each other; a first resistor having a first terminal coupled to the first terminal of the first transistor; a second resistor having a first terminal coupled to the first terminal of the second transistor; a comparator having: a first terminal coupled to a second terminal of the first resistor; a second terminal coupled to a second terminal of the second resistor; a third terminal coupled to the first terminal of the third transistor; a first current source having a control terminal coupled to a voltage threshold bias terminal, and an output terminal coupled to a second bias control terminal of the comparator; a second current source having a control terminal coupled to the voltage threshold bias terminal, and an output terminal coupled to a first bias control terminal of the comparator; and a third current source having a control terminal coupled to the voltage threshold terminal, and an output terminal coupled to a fourth terminal of the comparator.

In accordance to an embodiment, an integrated circuit (IC) includes: a switch including: a first transistor having a control terminal, a first current path terminal, and a second current path terminal; a second transistor having a control terminal, a first current path terminal, and a second current path terminal, and where the first current path terminal of the first transistor couples to the first current path terminal of the second transistor; and a switching control circuitry having a first control output terminal coupled to the control terminal of the first transistor, and a second control output terminal coupled to the control terminal of the second transistor, respectively; and an electronic circuit having a signal terminal coupled to the second current path terminal of the first transistor of the switch; and an input/output (I/O) terminal coupled to the second current path terminal of the second transistor.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 depicts a schematic diagram of an example of an integrated circuit (IC) having a protection switch configurable to limit a current flow between an electronic circuitry inside the IC and an input/output (I/O) terminal at the peripheral of the IC, in accordance with an embodiment of the present disclosure;

FIG. 2 depicts an example of a cross section of a silicon implementation of a transistor, in accordance with an embodiment of the present disclosure;

FIG. 3 depicts a schematic diagram of an example of an implementation of the switching control circuitry of the switch, in accordance with an embodiment of the present disclosure;

FIG. 4 depicts a schematic diagram of an example of a bias signal generator configurable to generate the second bias signal, in accordance with an embodiment of the present disclosure;

FIG. 5 depicts a schematic diagram of an example of a sense circuit configurable to sense a current along a path through the first transistor and the second transistor, in accordance with an embodiment of the present disclosure; and

FIG. 6 depicts a schematic diagram of an example of a voltage threshold bias generator configurable to generate the voltage threshold bias, in accordance with an embodiment of the present disclosure.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates various specific details to provide an in-depth understanding of several example embodiments according to the description. The embodiments may be obtained without one or more of the specific details, or with other methods, components, materials and the like. In some cases, known structures, materials or operations are not shown or described in detail so as not to obscure the different aspects of the embodiments. References to “an embodiment” in this description indicate that a particular configuration, structure or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

Some embodiments relate to current limit circuitry for a (e.g., high precision) protection switch.

In some applications, a configurable module performing multiple (e.g., sensing) functions may provide advantages for the module makers as well as factory architects, e.g., by reducing cost and complexity. Configuring a (e.g., high precision) digital-to-analog converter (DAC) and an analog-to-digital converter (ADC) may require (e.g., high voltage) multiplexers. Signal input/output (I/O) pins of such device may also benefit from protection, characterized by beyond supply tolerance, miswiring protection, pin stress with no power, short circuit protection, and/or, kilo-volt electrical fast transients, etc. Configurability and protection may be provided by separate devices which may occupy considerable board area.

Integrating configurable (e.g., high precision) DACs, ADCs, and protection circuitry in a single (e.g., universal IO) device may be beneficial. Such integration, however, may pose a challenge in handling the substrate for junction isolated processes, e.g., as biased substrates may be more suited for attaining precision whereas the configuration and protection devices may (e.g., preferably) be made with isolated substrates. A switch that can implement both the configurability and protection may also need to implement a current limit that is bidirectional, prevent excess isolation region currents, without altering the (e.g., high precision) current signal (e.g., less than a 100 nA) in the protection switch.

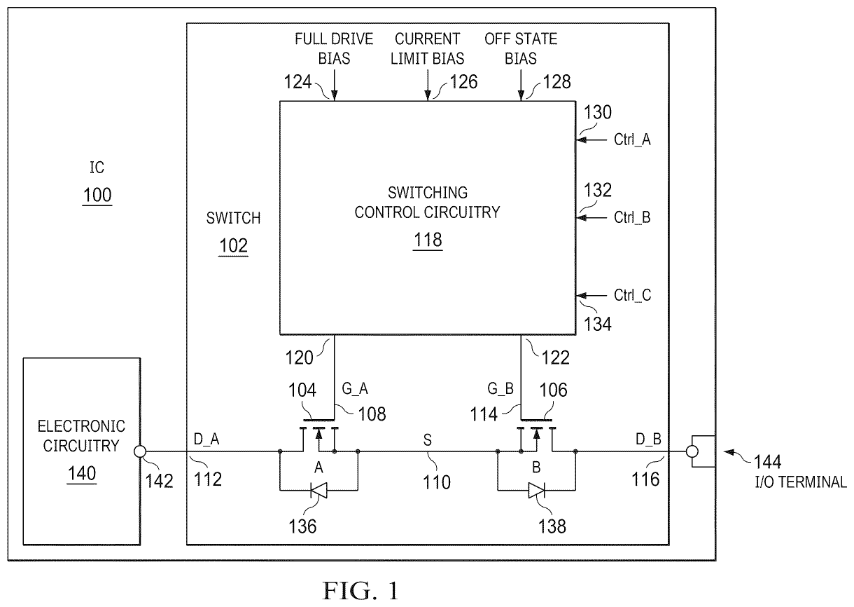

FIG. 1 depicts a schematic diagram of an example of an integrated circuit (IC) 100, according to an embodiment of the present disclosure. IC 100 includes a protection switch 102 and electronic circuitry 140.

In some embodiments, protection switch 102 is configurable to limit a current flow between an electronic circuitry 140 inside the IC 100 and an input/output (I/O) terminal 144.

In some embodiments, switch 102 includes switching control circuitry 118, a first transistor A/104 having a control terminal G_A/108, a first current path terminal S/110, and a second current path terminal D_A/112. The switch 102 further includes a second transistor B/106 having a control terminal G_B/114, a first current path terminal coupled to the first current path terminal S/110 of the first transistor 104, and a second current path terminal D_B/116. In one example, each of the first transistor 104 and the second transistor 106 is a field effect transistor (FET), e.g., MOSFET. In another example, each of the first transistor 104 and the second transistor 106 is a bipolar transistor, or any power semiconductor device, e.g., GaN FET, NexFET, etc. In one example, the control terminals 108 and 114 of the first transistor 104 and the second transistor 106 are gates of the first transistor 104 and the second transistor 106, respectively. In one example, the first current path terminals 110 of the first transistor 104 and the second transistor 106 are sources of the first transistor 104 and the second transistor 106, respectively. In one example, the second current path terminals 112 and 116 of the first transistor 104 and the second transistor 106 are drains of the first transistor 104 and the second transistor 106, respectively.

In some embodiments, switching control circuitry 118 includes a first control output terminal 120 coupled to the control terminal 108 of the first transistor 104, and a second control output terminal 122 coupled to the control terminal 114 of the second transistor 106, respectively.

In some embodiments, electronic circuitry 140 has a signal terminal 142 coupled to the second current path terminal 112 of the first transistor 104 of the switch 102 and the I/O terminal 144 is coupled to the second current path terminal 116 of the second transistor 106, thus forming a current path between the electronic circuitry 140 and the I/O terminal 144 through the first transistor 104 and the second transistor 106. In one example, the electronic circuitry 140 has signal I/O pins that need protection from outside current and/or voltage signals.

In some embodiments, the electronic circuitry 140 includes a data converter coupled to the second current path terminal 112 of the first transistor 104. For non-limiting examples, the data converter can be but is not limited to a digital-to-analog converter (DAC) or an analog-to-digital converter (ADC). In one example, the I/O terminal 144 is a power supply pin or pad of the IC 100.

In some embodiments, electronic circuitry 140 may be implemented as part of IC 100. In some embodiments, electronic circuitry 140 may be external to IC 100.

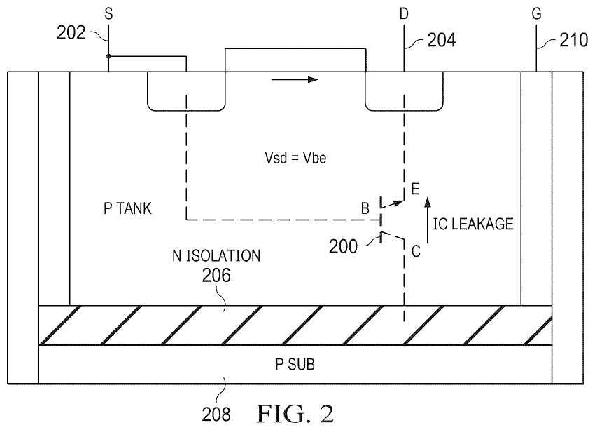

FIG. 2 depicts an example of a cross section of a silicon implementation of a transistor 200, which may be representative of any of the transistors discussed herein. With source S/202 to drain D/204 current flow, excess current may result in exponentially larger currents from the isolation region 206 separating the transistor 200 from the biased substrate 208 due to bipolar transistor action. It may be beneficial to limit current limit the signal current in such a way as to prevent excess currents in the isolation region 206. This may enable precision operation as leakage currents into the gate G/210 are much smaller than the resolution required for the high precision current path.

During normal operation, the switching control circuitry 118 of the switch 102 is configurable to send a first control signal to the control terminal 108 of the first transistor 104 and a second control signal to the control terminal 114 of the second transistor 106, respectively. In one example, the switching control circuitry 118 of the switch 102 is configurable to turn the first transistor 104 and the second transistor 106 on or off via the first control signal and the second control signal, respectively. In one example, the switching control circuitry 118 of the switch 102 is configurable to set one of the first transistor 104 and the second transistor 106 in a saturation region via the first control signal and/or the second control signal when the first transistor and the second transistor are turned on. By controlling the switching of the first transistor 104 and the second transistor 106, the switching control circuitry 118 of the switch 102 is configurable to control and limit a current flow along the current path between the electronic circuitry 140 and the I/O terminal 144 through the first transistor 104 and the second transistor 106 in both directions (i.e., bidirectional control).

As shown in the example of FIG. 1, the switching control circuitry 118 of the switch 102 has a plurality of bias control signal input terminals including a first bias control signal input terminal 130 configurable to receive a first bias control signal Ctrl_A, a second bias control signal input terminal 132 configurable to receive a second bias control signal Ctrl_B, and a third bias control signal input terminal 134 configurable to receive a third bias control signal Ctrl_C. In one example, the switching control circuitry 118 has a plurality of bias signal input terminals including a first bias signal input terminal 124 configurable to receive a first bias signal Full_Drive_Bias, a second bias signal input terminal 126 configurable to receive a second bias signal Current_Limit_Bias, and a third bias signal input terminal 128 configurable to receive a third bias signal Off_State_Bias. In one example, the first bias signal turns on the pair of back to back transistors 104 and 106, which provides a low impedance path between the electronic circuitry 140 and the I/O terminal 144 through the first and the second transistors. The third bias signal turns off the pair of back to back transistors 104 and 106, and the back body diodes 136 and 138 of the first and the second transistors creates a high impedance between electronic circuitry 140 and the I/O terminal 144. The second bias signal puts at least one of the pair of back to back transistors 104 and 106 in saturation, which limits the current flowing between the electronic circuitry 140 and the I/O terminal 144.

During normal operation, the switching control circuitry 118 is configurable to provide a first control signal to the control terminal 108 of the first transistor 104 via the first control output terminal 120 to transition the first transistor 104 between a linear region and a saturation region based on the first bias control signal Ctrl_A. The switching control circuitry 118 of the switch 102 is also configurable to provide a second control signal to the control terminal 114 of the second transistor 106 via the second control output terminal 122 to transition the second transistor 106 between a linear region and a saturation region based on the second bias control signal Ctrl_B. In one example, the switching control circuitry 118 of the switch 102 is configurable to provide the first and the second control signals Ctr_A and Ctrl_B to the control terminals of the first and the second transistors to turn the first and the second transistors on or off based on the third bias control signal Ctrl_C.

In one example, the switching control circuitry 118 is configurable to transition one of the two transistors 104 and 106 in the switch 102 to saturation and limit the current while maintaining the other transistor on which the current is sensed in its linear region. In one example, the switching control circuitry 118 of the switch 102 is configurable to sense a first current flowing through the first transistor 104 when the first transistor 104 is in the linear region and the second transistor 106 is in the saturation region. The switching control circuitry 118 of the switch 102 is configurable to sense a second current flowing through the second transistor 106 when the second transistor 106 is in the linear region and the first transistor is in the saturation region. In one example, the switching control circuitry 118 of the switch 102 is configurable to limit the current flow along the current path between the electronic circuitry 140 and the I/O terminal 144 through the first transistor 104 and the second transistor 106.

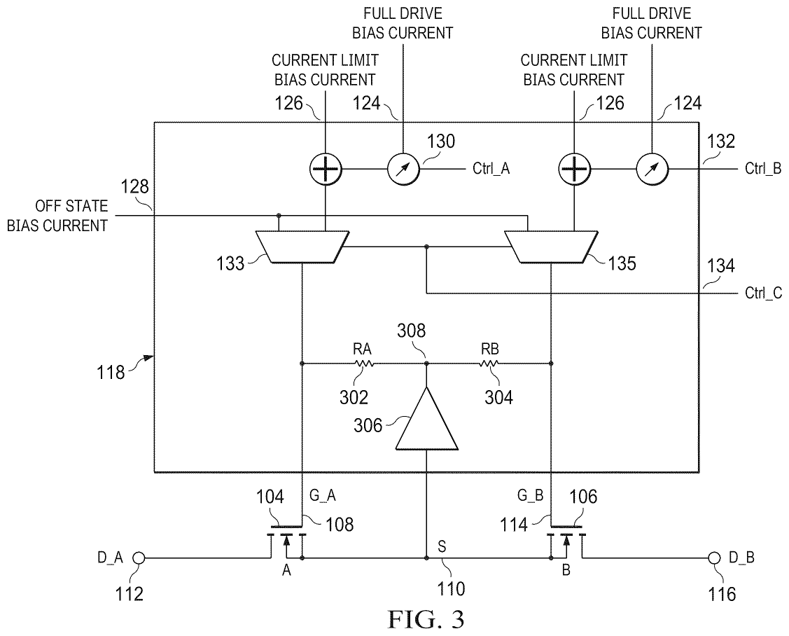

FIG. 3 depicts a schematic diagram of an example of an implementation of the switching control circuitry 118 of the switch 102, wherein the first bias signal, the second bias signal, and the third bias signal at the first bias signal input terminal 124, the second bias signal input terminal 126, and the third bias signal input terminal 128, respectively, are current signals, which may be referred as Full Drive Bias Current, Current Limit (Keep Alive) Bias Current, and Off State Bias Current, respectively. As shown in FIG. 3, a first Mux 133 and a second Mux 135 each receives the Off State Bias Current and the sum of Full Drive Bias Current and Current Limit Bias Current as its two inputs and provides a current output to the control terminals 108 and 114 of the first transistor 104 and the second transistor 106 as controlled by the third bias control signal Ctrl_C. Each of the control terminals 108 and 114 of the first transistor 104 and the second transistor 106 is driven by the sum of Full Drive Bias Current and Current Limit Bias Current when the first transistor 104 and the second transistor 106 are switched ON (in linear region/state) by the third bias control signal Ctrl_C, providing a low impedance path between the second current path terminals 112 and 116 of the first transistor 104 and the second transistor 106, respectively. When the first transistor 104 and the second transistor 106 are switched OFF by the third bias control signal Ctrl_C at Off State Bias Current, the body diodes of the first transistor 104 and the second transistor 106 provide back to back diodes 136 and 138 between the second current path terminals 112 and 116, creates a high impedance between the two terminals. Once current Ctrl_A or Ctrl_B is asserted to regulate and set the current limit, Full Drive Bias Current is reduced by Ctrl_A or Ctrl_B. To prevent either of the first transistor 104 and the second transistor 106 from turning off, a minimum Current Limit Bias Current sets the lower limit at the control terminal of either the first transistor 104 or the second transistor 106 to keep the corresponding transistor on wherein that corresponding transistor is biased in saturation and supports a fixed current limit.

In one example, the switching control circuitry 118 is configurable to generate the first control signal to the control terminal 108 of the first transistor 104 and the second control signal to the control terminal 114 of the second transistor 106 using a first resistor RA 302 and a second resistor RB 304, respectively, using the current(s) from the bias signals Full Drive Bias Current, Current Limit Bias Current, and Off State Bias Current discussed above. As shown in FIG. 3, the first resistor 302 is coupled between the control terminal 108 of the first transistor 104 and a terminal 308, and the second resistor 304 is coupled between the control terminal 114 of the second transistor 106 and the terminal 308. In one example, a buffer 306 is coupled between the terminal 308 and the first current path terminal 110 of the first and the second transistors, wherein the buffer 306 is configurable to mirror the voltage on the first current path terminals 110. Under such configuration, the first resistor 302 and the second resistor 304 are floating between the gates and sources of the first and the second transistors, respectively.

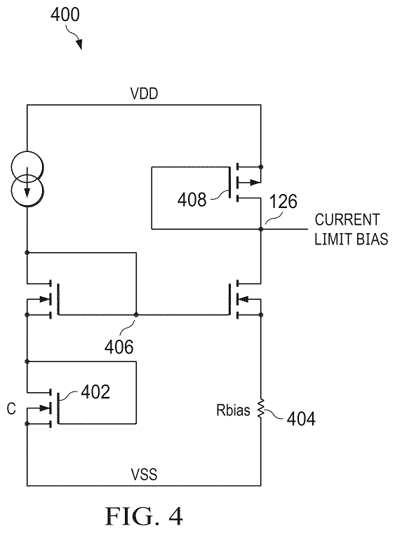

FIG. 4 depicts a schematic diagram of an example of a bias signal generator 400, according to an embodiment of the present disclosure.

In some embodiments, bias signal generator 400 is coupled to the second bias signal input terminal 126 and configurable to generate the second bias signal Current Limit Bias Current discussed above. In one example, the bias signal generator 400 includes a third transistor C/402, which may be a scaled down replica and the same type as the first transistor 104 and the second transistor 106. The voltage over the third transistor 402 is imposed on a scaled third resistor Rbias 404, which may be of the same type of the first and the second resistors 302 and 304 used to generate the first and second control signals of the first and the second transistors as discussed above. The current in the third resistor 404 may be used to generate the Current Limit Bias Current. Diode connected transistor 408 may be biased with that Current Limit Bias Current and generates the Current limit bias voltage signal for the second bias signal input terminal 126.

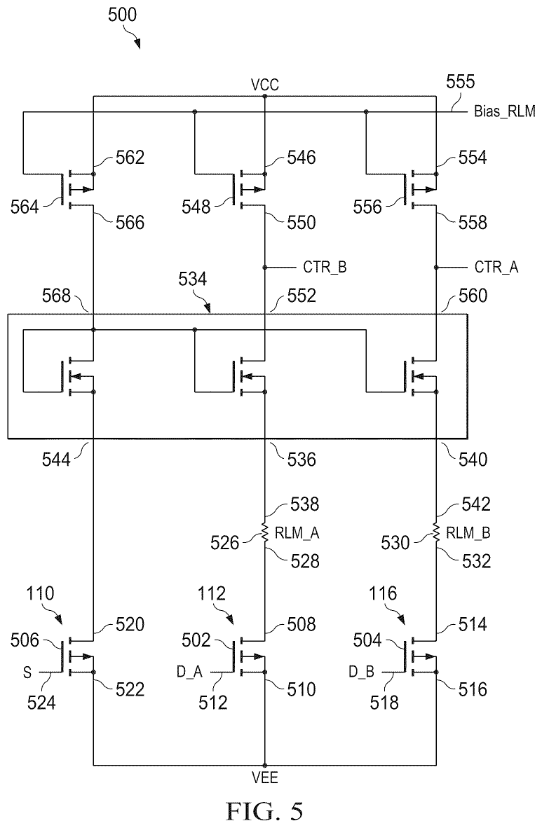

FIG. 5 depicts a schematic diagram of an example of a sense circuit 500, according to an embodiment of the present disclosure.

In some embodiments, sense circuit 500 is configurable to sense a current along a path through the first transistor 104 and the second transistor 106. In some embodiments, the sense circuit 500 includes a first input terminal 512 coupled to the second current path terminal 112 of the first transistor 104, a second input terminal 518 coupled to the second current path terminal 116 of the second transistor 106, and a third input terminal 524 coupled to the first current path terminals 110 of the first transistor 104 and the second transistor 106. The sense circuit 500 further includes a first output terminal 552 coupled to the second bias control signal input terminal 132 of the switching control circuitry 118 and a second output terminal 560 coupled to the first bias control signal input terminal 130 of the of the switching control circuitry 118.

As shown in FIG. 5, the sense circuit 500 has a plurality of transistors including a first transistor 502 having a first terminal 508, a second terminal 510 and a control terminal (the first input terminal) 512 coupled to the second current path terminal 112 of the first transistor 104 of the switch 102. The sense circuit 500 also has a second transistor 504 having a first terminal 514, a second terminal 516, and a control terminal (the second input terminal) 518 coupled to the second current path terminal 116 of the second transistor 106 of the switch 102. The sense circuit 500 also has a third transistor 506 having a first terminal 520, a second terminal 522, and a control terminal (the third input terminal) 524 coupled to the first current path terminals 110 of the first transistor 104 and the second transistor 106 of the switch 102, and wherein the second terminals of the first, second and third transistors are coupled to each other. The sense circuit 500 further includes a first resistor 526/RLM_A having a first terminal 528 coupled to the first terminal 508 of the first transistor 502. The sense circuit 500 further includes a second resistor 530/RLM_B having a first terminal 532 coupled to the first terminal 514 of the second transistor 504.

In one example, the control terminal 512 coupled to the second current path terminal 112/D_A of the first transistor 104 and the control terminal 518 coupled to the second current path terminal 116/D_B of the second transistor 106 may offer high impedance so that the signal current through the first and the second transistors is sensed but not altered. This may enable precision operation as leakage currents into the control terminals may be much smaller than the resolution required for the high precision current path. In one example, the sensed quantity is the source to drain voltage (Vsd) of the first and the second transistors 102/104, which relates to both the signal current through the ON resistance (Rds_on) of the first and the second transistors 102/104 as well as the base emitter voltage (Vbe) that controls the excess collector current from the isolation region 206 as shown in FIG. 2.

In one example, the sense circuit 500 further includes a comparator 534 having a first input terminal 536 coupled to a second terminal 538 of the first resistor 526, a second input terminal 540 coupled to a second terminal 542 of the second resistor 530, and a third input terminal 544 coupled to the first terminal 520 of the third transistor 506. In one example, the sense circuit 500 further includes a first current source 546 having a control terminal 548 coupled to a voltage threshold bias terminal 555, and an output terminal 550 coupled to a second bias control terminal (the first output terminal) 552 of the comparator 534. The sense circuit 500 further includes a second current source 554 having a control terminal 556 coupled to the voltage threshold terminal bias 555, and an output terminal 558 coupled to a first bias control terminal (the second output terminal) 560 of the comparator 534. The sense circuit 500 further includes a third current source 562 having a control terminal 564 coupled to the voltage threshold bias terminal 555, and an output terminal 566 coupled to a terminal 568 of the comparator 534.

In one example, if the voltage at the second current path terminal 112/D_A of the first transistor 104 or the second current path terminal 116/D_B of the second transistor 106 is less than the source voltage at the first current path terminals 110/S of the first transistor 104 and the second transistor 106 added to the voltage across RLM_A or RLM_B, the sense circuit 500 is configurable to pull the respective signal CTR_B or CTR_A lower than VCC. This may indicate a state of excess current and may be used by the switch 102 to switch control of the bias to the first and the second transistors of the switch 102. Note that if the first transistor 104 of the switch 102 reaches this state, bias to the second transistor 106 is changed to limit current and maintain the current limited state and vice versa. For a non-limiting example, if the voltage at the second current path terminal 112/D_A of the first transistor 104 or the second current path terminal 116/D_B of the second transistor 106 is less than the source voltage at the first current path terminals 110/S of the first transistor 104 and the second transistor 106 by more than, e.g., approximately 200 mV, unwanted collector current from the isolation region 206 to the drain may be high enough to impact the signal precision, and the current can be limited. Hence the drops on resistance limits (RLMs) are set appropriately to provide this threshold by voltage threshold bias Bias_RLM at the voltage threshold bias terminal 555.

In one example, the comparator 534 is configurable to generate the first bias control signal Ctrl_A at the first bias control terminal 560 by comparing a second signal at the second input terminal 518, which is coupled to the second current path terminal 116/D_B of the second transistor 106 of the switch 102, plus a second voltage drop over the second resistor 530 with a third signal at the third input terminal 524, which is coupled to the first current path terminals 110/S of the first transistor 104 and the second transistor 106, wherein the first bias control signal Ctrl_A is used to control the first transistor 104 of the switch 102. In one example, the second voltage drop over the second resistor is limited by the voltage threshold bias Bias_RLM at the voltage threshold terminal 555. In one example, the comparator 534 is configurable to generate a second bias control signal Ctrl_B at the second bias control terminal 552 by comparing a first signal at the first input terminal 512, which is coupled to the second current path terminal 112/D_A of the first transistor 104 of the switch 102, plus a first voltage drop over the first resistor 526 with the third signal at the third input terminal 524, wherein the second bias control signal Ctrl_B is used to control the second transistor 106 of the switch 102. In one example, the first voltage drop over the first resistor 526 may be limited by the voltage threshold Bias_RLM at the voltage threshold terminal 555.

The ON state resistance (Rds_on) of the first and the second transistors 102/104 may vary considerably with process and temperature. So, for a given current, the voltage drops (Vds or Vsd) on the first and the second transistors 102/104 may also vary. To limit the variations in detection threshold, the first and the second voltage drops across RLM_A and RLM_B need to track the voltage developed on first and the second transistors 102/104, respectively, at the target current limit.

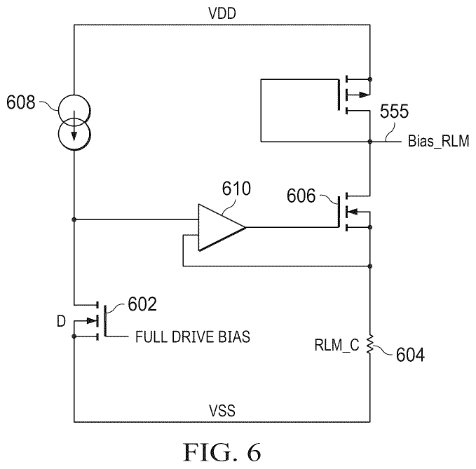

FIG. 6 depicts a schematic diagram of an example of a voltage threshold bias generator 600, according to an embodiment of the present disclosure. Voltage threshold bias generator 600 is coupled to the voltage threshold terminal 555 of the sense circuit 500 and configurable to generate the voltage threshold Bias_RLM discussed above. As shown in FIG. 6, the voltage threshold bias generator 600 includes a fourth transistor D/602, which may be a scaled down replica and of the same type as the first and the second transistors 102/104 of the switch 102. In one example, the voltage threshold bias generator 600 includes a third resistor 604/RLM_C, which may be a scaled down and of the same type as the first and the second resistors 526/530 (RLM_A/RLM_B) of the sense circuit 500. A current source 608 provides a bias current to the fourth transistor 602. The voltage over the fourth transistor 602 may be imposed on the scaled third resistor RLM_C 604 via a buffer 610, wherein the current in the third resistor 604 is used to generate the voltage threshold Bias_RLM at the voltage threshold terminal 555 via a following circuitry 606. As such, the voltage drops across RLM_A and RLM_B track the ON state voltage drop on the first and the second transistors 102/104 of the switch 102 to the first order and provide a consistent threshold for current limit.

Example embodiments of the present disclosure are summarized here. Other embodiments can also be understood from the entirety of the specification and the claims filed herein.

Example 1. An electronic circuit including: a first transistor having a control terminal, a first current path terminal, and a second current path terminal; a second transistor having a control terminal, a first current path terminal, and a second current path terminal, where the first current path terminal of the first transistor is coupled to the first current path terminal of the second transistor; and a control circuit configurable to: receive a first bias control signal; receive a second bias control signal; provide a first control signal to the control terminal of the first transistor to transition the first transistor between a linear region and a saturation region based on the first bias control signal; and provide a second control signal to the control terminal of the second transistor to transition the second transistor between a linear region and a saturation region based on the second bias control signal.

Example 2. The electronic circuit of example 1, where the control circuit includes: a first bias signal input terminal configurable to receive a first bias signal; a second bias signal input terminal configurable to receive a second bias signal; a first bias control signal input terminal configurable to receive the first bias control signal; a second bias control signal input terminal configurable to receive the second bias control signal; a first control output terminal configurable to provide the first control signal to the control terminal of the first transistor; and a second control output terminal configurable to provide the second control signal to the control terminal of the second transistor.

Example 3. The electronic circuit of one of examples 1 or 2, where the control circuit is configurable to: sense a first current flowing through the first transistor when the first transistor is in the linear region and the second transistor is in the saturation region; and sense a second current flowing through the second transistor when the second transistor is in the linear region and the first transistor is in the saturation region.

Example 4. The electronic circuit of one of examples 1 to 3, where the control circuit is configurable to limit a current flow along a current path through the first transistor and the second transistor.

Example 5. The electronic circuit of one of examples 1 to 4, where each of the first transistor and the second transistor is a GaN field effect transistor (FET).

Example 6. The electronic circuit of one of examples 1 to 5, where each of the first transistor and the second transistor is a power semiconductor device.

Example 7. The electronic circuit of one of examples 1 to 6, where the control terminals of the first transistor and the second transistor are gates of the first transistor and the second transistor, respectively.

Example 8. The electronic circuit of one of examples 1 to 7, where the first current path terminals of the first transistor and the second transistor are sources of the first transistor and the second transistor, respectively.

Example 9. The electronic circuit of one of examples 1 to 8, where the second current path terminals of the first transistor and the second transistor are drains of the first transistor and the second transistor, respectively.

Example 10. The electronic circuit of one of examples 1 to 9, where the control circuit is configurable to: receive a third bias control signal; provide the first and the second control signals to the control terminals of the first and the second transistors to turn the first and the second transistors on or off based on the third bias control signal.

Example 11. The electronic circuit of one of examples 1 to 10, where the control circuit is configurable to receive a third bias signal.

Example 12. The electronic circuit of one of examples 1 to 11, where the first and the second transistors form a pair of back-to-back diodes when the first and the second transistors are turned off.

Example 13. The electronic circuit of one of examples 1 to 12, where the first bias signal and the second bias signal are current signals.

Example 14. The electronic circuit of one of examples 1 to 13, where the control circuit is configurable to: generate the first control signal using a first resistor; and generate the second control signal based using a second resistor that is coupled to the first resistor and a buffer.

Example 15. The electronic circuit of one of examples 1 to 14, where: the first resistor is coupled between the control terminal of the first transistor and a first terminal; the second resistor is coupled between the control terminal of the second transistor and the first terminal; and the buffer is coupled between the first terminal and the first current path terminal of the first transistor and the first current path terminal of the second transistor.

Example 16. The electronic circuit of one of examples 1 to 15, further including a second bias signal generator coupled to the second bias signal input terminal, where the second bias signal generator includes a third transistor that is of the same type as the first and the second transistors, and a third resistor that is of the same type as the first and the second resistors.

Example 17. The electronic circuit of one of examples 1 to 16, further including a sense circuit having: a first input terminal coupled to the second current path terminal of the first transistor; a second input terminal coupled to the second current path terminal of the second transistor; a third input terminal coupled to the first current path terminals of the first transistor and the second transistor; a first output terminal coupled to the second bias control signal input terminal of the control circuit; and a second output terminal coupled to the first bias control signal input terminal of the control circuit.

Example 18. The electronic circuit of one of examples 1 to 17, further including a voltage threshold bias generator coupled to a voltage threshold bias terminal of the sense circuit, where the voltage threshold generator includes a fourth transistor that is of the same type as the first and the second transistors, and a third resistor that is of the same type as the first and the second resistors.

Example 19. The electronic circuit one of examples 1 to 18, where the electronic circuit is an integrated circuit including: a data converter coupled to the second current path terminal of the first transistor; and a pin or pad coupled to the second current path terminal of the second transistor.

Example 20. An electronic circuit including: a first transistor having a first terminal, a second terminal, and a control terminal coupled to a first signal terminal; a second transistor having a first terminal, a second terminal, and a control terminal coupled to a second signal terminal; a third transistor having a first terminal, a second terminal, and a control terminal coupled to a third signal terminal, and where the second terminals of the first, second and third transistors are coupled to each other; a first resistor having a first terminal coupled to the first terminal of the first transistor; a second resistor having a first terminal coupled to the first terminal of the second transistor; a comparator having: a first terminal coupled to a second terminal of the first resistor; a second terminal coupled to a second terminal of the second resistor; a third terminal coupled to the first terminal of the third transistor; a first current source having a control terminal coupled to a voltage threshold bias terminal, and an output terminal coupled to a second bias control terminal of the comparator; a second current source having a control terminal coupled to the voltage threshold bias terminal, and an output terminal coupled to a first bias control terminal of the comparator; and a third current source having a control terminal coupled to the voltage threshold terminal, and an output terminal coupled to a fourth terminal of the comparator.

Example 21. The electronic circuit of example 20, where the comparator is configurable to generate a first bias control signal at the first bias control terminal by comparing a second signal at the second signal terminal plus a second voltage drop over the second resistor with a third signal at the third signal terminal, where the first bias control signal is used to control a fourth transistor.

Example 22. The electronic circuit of one of examples 20 or 21, where the second voltage drop over the second resistor is limited by a voltage threshold bias at the voltage threshold bias terminal.

Example 23. The electronic circuit of one of examples 20 to 22, where the comparator is configurable to generate a second bias control signal at the second bias control terminal by comparing a first signal at the first input terminal plus a first voltage drop over the first resistor with the third signal at the third signal terminal, where the second bias control signal is used to control a fifth transistor.

Example 24. The electronic circuit of one of examples 20 to 23, where the first voltage drop over the first resistor is limited by the voltage threshold at the voltage threshold bias terminal.

Example 25. The electronic circuit of one of examples 20 to 24, where the voltage threshold bias is generated using a sixth transistor that is of the same type as the fourth and the fifth transistors, and a third resistor that is of the same type as the first and the second resistors.

Example 26. An integrated circuit (IC) including: a switch including: a first transistor having a control terminal, a first current path terminal, and a second current path terminal; a second transistor having a control terminal, a first current path terminal, and a second current path terminal, and where the first current path terminal of the first transistor couples to the first current path terminal of the second transistor; and a switching control circuitry having a first control output terminal coupled to the control terminal of the first transistor, and a second control output terminal coupled to the control terminal of the second transistor, respectively; and an electronic circuit having a signal terminal coupled to the second current path terminal of the first transistor of the switch; and an input/output (I/O) terminal coupled to the second current path terminal of the second transistor.

Example 27. The IC of example 26, where the electronic circuit includes a digital-to-analog converter (DAC).

Example 28. The IC of one of examples 26 or 27, where the electronic circuit includes an analog-to-digital converter (ADC).

Example 29. The IC of one of examples 26 to 28, where the I/O terminal is a power supply terminal.

Example 30. The IC of one of examples 26 to 29, where the switching control circuitry of the switch is configurable to: send a first control signal to the control terminal of the first transistor; and send a second control signal to the control terminal of the second transistor.

Example 31. The IC of one of examples 26 to 30, where the switching control circuitry of the switch is configurable to turn the first transistor and the second transistor on or off via the first control signal and the second control signal, respectively.

Example 32. The IC of one of examples 26 to 31, where the switching control circuitry of the switch is configurable to set one of the first transistor and the second transistor in a saturation region via the first control signal and/or the second control signal when the first transistor and the second transistor are turned on.

Example 33. The IC of one of examples 26 to 32, where the switching control circuitry of the switch is configurable to limit a current flow along a current path between the electronic circuitry and the I/O terminal through the first transistor and the second transistor.

In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. An electronic circuit comprising:
a first transistor having a control terminal, a first current path terminal, and a second current path terminal;
a second transistor having a control terminal, a first current path terminal, and a second current path terminal, wherein the first current path terminal of the first transistor is coupled to the first current path terminal of the second transistor; and
a control circuit configurable to:
receive a first bias control signal;
receive a second bias control signal;
provide a first control signal to the control terminal of the first transistor to transition the first transistor between a linear region and a saturation region based on the first bias control signal; and
provide a second control signal to the control terminal of the second transistor to transition the second transistor between a linear region and a saturation region based on the second bias control signal.

2. The electronic circuit of claim 1, wherein the control circuit includes:
a first bias signal input terminal configurable to receive a first bias signal;
a second bias signal input terminal configurable to receive a second bias signal;
a first bias control signal input terminal configurable to receive the first bias control signal;
a second bias control signal input terminal configurable to receive the second bias control signal;
a first control output terminal configurable to provide the first control signal to the control terminal of the first transistor; and
a second control output terminal configurable to provide the second control signal to the control terminal of the second transistor.

3. The electronic circuit of claim 2, wherein the first bias signal and the second bias signal are current signals.

4. The electronic circuit of claim 1, wherein the control circuit is configurable to:
sense a first current flowing through the first transistor when the first transistor is in the linear region and the second transistor is in the saturation region; and
sense a second current flowing through the second transistor when the second transistor is in the linear region and the first transistor is in the saturation region.

5. The electronic circuit of claim 1, wherein the control circuit is configurable to limit a current flow along a current path through the first transistor and the second transistor.

6. The electronic circuit of claim 1, wherein each of the first transistor and the second transistor is a GaN field effect transistor (FET).

7. The electronic circuit of claim 1, wherein the control circuit is configurable to:
receive a third bias control signal;
provide the first and the second control signals to the control terminals of the first and the second transistors to turn the first and the second transistors on or off based on the third bias control signal.

8. The electronic circuit of claim 1, wherein the control circuit is configurable to receive a third bias signal.

9. The electronic circuit of claim 1, wherein the first and the second transistors form a pair of back-to-back diodes when the first and the second transistors are turned off.

10. The electronic circuit of claim 1, wherein the control circuit is configurable to:
generate the first control signal using a first resistor; and
generate the second control signal based using a second resistor that is coupled to the first resistor and a buffer.

11. The electronic circuit of claim 10, wherein:
the first resistor is coupled between the control terminal of the first transistor and a first terminal;
the second resistor is coupled between the control terminal of the second transistor and the first terminal; and
the buffer is coupled between the first terminal and the first current path terminal of the first transistor and the first current path terminal of the second transistor.

12. The electronic circuit of claim 11, further comprising a second bias signal generator coupled to the second bias signal input terminal, wherein the second bias signal generator includes a third transistor that is of the same type as the first and the second transistors, and a third resistor that is of the same type as the first and the second resistors.

13. The electronic circuit of claim 12, further comprising a sense circuit having:
a first input terminal coupled to the second current path terminal of the first transistor;
a second input terminal coupled to the second current path terminal of the second transistor;
a third input terminal coupled to the first current path terminals of the first transistor and the second transistor;
a first output terminal coupled to the second bias control signal input terminal of the control circuit; and
a second output terminal coupled to the first bias control signal input terminal of the control circuit.

14. The electronic circuit of claim 13, further comprising a voltage threshold bias generator coupled to a voltage threshold bias terminal of the sense circuit, wherein the voltage threshold generator includes a fourth transistor that is of the same type as the first and the second transistors, and a third resistor that is of the same type as the first and the second resistors.

15. The electronic circuit claim 1, wherein the electronic circuit is an integrated circuit comprising:
a data converter coupled to the second current path terminal of the first transistor; and
a pin or pad coupled to the second current path terminal of the second transistor.

16. An electronic circuit comprising:
a first transistor having a first terminal, a second terminal, and a control terminal coupled to a first signal terminal;
a second transistor having a first terminal, a second terminal, and a control terminal coupled to a second signal terminal;
a third transistor having a first terminal, a second terminal, and a control terminal coupled to a third signal terminal, and wherein the second terminals of the first, second and third transistors are coupled to each other;
a first resistor having a first terminal coupled to the first terminal of the first transistor;
a second resistor having a first terminal coupled to the first terminal of the second transistor;
a comparator having:
a first terminal coupled to a second terminal of the first resistor;
a second terminal coupled to a second terminal of the second resistor;
a third terminal coupled to the first terminal of the third transistor;
a first current source having a control terminal coupled to a voltage threshold bias terminal, and an output terminal coupled to a second bias control terminal of the comparator;
a second current source having a control terminal coupled to the voltage threshold bias terminal, and an output terminal coupled to a first bias control terminal of the comparator; and
a third current source having a control terminal coupled to the voltage threshold terminal, and an output terminal coupled to a fourth terminal of the comparator.

17. The electronic circuit of claim 16, wherein the comparator is configurable to generate a first bias control signal at the first bias control terminal by comparing a second signal at the second signal terminal plus a second voltage drop over the second resistor with a third signal at the third signal terminal, wherein the first bias control signal is used to control a fourth transistor.

18. The electronic circuit of claim 17, wherein the second voltage drop over the second resistor is limited by a voltage threshold bias at the voltage threshold bias terminal.

19. The electronic circuit of claim 17, wherein the comparator is configurable to generate a second bias control signal at the second bias control terminal by comparing a first signal at the first input terminal plus a first voltage drop over the first resistor with the third signal at the third signal terminal, wherein the second bias control signal is used to control a fifth transistor.

20. The electronic circuit of claim 19, wherein the first voltage drop over the first resistor is limited by the voltage threshold at the voltage threshold bias terminal.

21. The electronic circuit of claim 17, wherein the voltage threshold bias is generated using a sixth transistor that is of the same type as the fourth and the fifth transistors, and a third resistor that is of the same type as the first and the second resistors.

22. An integrated circuit (IC) comprising:
a switch including:
a first transistor having a control terminal, a first current path terminal, and a second current path terminal;
a second transistor having a control terminal, a first current path terminal, and a second current path terminal, and wherein the first current path terminal of the first transistor couples to the first current path terminal of the second transistor; and
a switching control circuitry having a first control output terminal coupled to the control terminal of the first transistor, and a second control output terminal coupled to the control terminal of the second transistor, respectively; and
an electronic circuit having a signal terminal coupled to the second current path terminal of the first transistor of the switch; and
an input/output (I/O) terminal coupled to the second current path terminal of the second transistor.

23. The IC of claim 22, wherein the I/O terminal is a power supply terminal.

24. The IC of claim 22, wherein the switching control circuitry of the switch is configurable to:
send a first control signal to the control terminal of the first transistor;
send a second control signal to the control terminal of the second transistor; and
turn the first transistor and the second transistor on or off via the first control signal and the second control signal, respectively.

25. The IC of claim 22, wherein the switching control circuitry of the switch is configurable to set one of the first transistor and the second transistor in a saturation region when the first transistor and the second transistor are turned on.

26. The IC of claim 25, wherein the switching control circuitry of the switch is configurable to limit a current flow along a current path between the electronic circuitry and the I/O terminal through the first transistor and the second transistor.
